(19) United States
(12) Patent Application Publication
(10) Pub. No.: US 2023/0335516 A1
(43) Pub. Date: Oct. 19, 2023

(54) MANUFACTURING PACKAGE BY SOLDERABLE OR SINTERABLE METALLIC CONNECTION STRUCTURE APPLIED ON SACRIFICIAL CARRIER

(71) Applicant: Infineon Technologies AG, Neubiberg (DE)

(72) Inventors: Chee Yang NG, Muar (MY); Chew Yeek LAU, Muar (MY); Swee Kah LEE, Melaka (MY); Joseph Victor SOOSAI PRAKASAM, Chennai (IN); Hui Khin TAN, Melaka (MY)

(73) Assignee: Infineon Technologies AG, Neubiberg (DE)

(21) Appl. No.: 18/125,252

(22) Filed: Mar. 23, 2023

(30) Foreign Application Priority Data
Apr. 13, 2022 (DE) 10 2022 109 053.1

(51) Int. Cl. H01L 23/00; H01L 23/31; H01L 21/56; H01L 23/498

(52) U.S. Cl. CPC H01L 24/03; H01L 23/3121; H01L 24/32; H01L 24/11; H01L 21/56; H01L 23/49838; H01L 24/13; H01L 2924/141; H01L 2224/16225; H01L 2924/182

(57) ABSTRACT

A method of manufacturing a package is disclosed. In one example, the method comprises applying a metallic connection structure, which comprises a solder or sinter material, on a sacrificial carrier. An electronic component is mounted on the metallic connection structure. At least part of the electronic component and of the metallic connection structure is encapsulated. Thereafter, the sacrificial carrier is removed to thereby expose at least part of the metallic connection structure.

### CROSS-REFERENCE TO RELATED APPLICATION

This Utility Patent Application claims priority to German Patent Application No. 10 2022 109 053.1 filed Apr. 13, 2022, which is incorporated herein by reference.

### BACKGROUND

### Technical Field

Various embodiments relate generally to a package, and a method of manufacturing a package.

### Description of the Related Art

A conventional electronic system may comprise an electronic component soldered on a chip carrier such as a leadframe, and may be optionally molded using a mold compound as an encapsulant.

There may be a need to manufacture a package in a simple and efficient way and with high performance.

### SUMMARY

According to an exemplary embodiment, a method of manufacturing a package is provided, wherein the method comprises applying a metallic connection structure, which comprises a solder or sinter material, on a sacrificial carrier, mounting an electronic component on the metallic connection structure, encapsulating at least part of the electronic component and of the metallic connection structure by an encapsulant, and thereafter removing the sacrificial carrier to thereby expose at least part of the metallic connection structure.

According to another exemplary embodiment, a package is provided which comprises a metallic connection structure, an electronic component mounted on the metallic connection structure, and an encapsulant encapsulating at least part of the electronic component and of the metallic connection structure, wherein an exposed part of the metallic connection structure comprises an intermetallic compound.

According to an exemplary embodiment, a simple and efficient package manufacture may be made possible by applying a solderable or sinterable metallic connection structure on a sacrificial or temporary carrier, which will be removed later before completing the manufacturing process. After assembling an electronic component on the applied metallic connection structure and subsequent encapsulation for firmly holding the parts together, the sacrificial carrier may be removed for rendering the metallic connection structure at least partially accessible. This exposing process may simplify subsequent electrical and mechanical coupling of the package with an electronic periphery. The mentioned manufacturing process may ensure a compact design of the manufactured package, since the sacrificial carrier may be removed so that a carrier-less package with small dimensions can be obtained.

Advantageously, an intermetallic compound may be formed as an interface between the sacrificial carrier and the solderable or sinterable metallic connection structure when the sacrificial carrier comprises or consists of a metallic material. Such an intermetallic compound may be exposed in the readily manufactured package and may promote an electric and mechanical connection of the package with an electronic periphery, such as a printed circuit board. Descriptively speaking, the presence of the intermetallic compound may be a fingerprint of embodiments of the above-described manufacturing method when an appropriate metallic sacrificial carrier is implemented.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a cross-sectional view of a package according to an exemplary embodiment.

FIG. 2 illustrates a cross-sectional view of a package according to another exemplary embodiment.

FIG. 3 to FIG. 10 are cross-sectional views of structures obtained during manufacturing a package, as the one shown in FIG. 1, according to an exemplary embodiment.

FIG. 11 illustrates a cross-sectional view of a package according to still another exemplary embodiment.

FIG. 12 to FIG. 14 are plan views of structures obtained during manufacturing packages according to an exemplary embodiment.

FIG. 15 illustrates a cross-sectional view of a package according to still another exemplary embodiment.

FIG. 16 illustrates a cross-sectional view of a package according to still another exemplary embodiment.

### DETAILED DESCRIPTION

According to an exemplary embodiment, a method of manufacturing a package is provided, wherein the method comprises applying a metallic connection structure, which comprises a solder or sinter material, on a sacrificial carrier, mounting an electronic component on the metallic connection structure, encapsulating at least part of the electronic component and of the metallic connection structure by an encapsulant, and thereafter removing the sacrificial carrier to thereby expose at least part of the metallic connection structure.

According to another exemplary embodiment, a package is provided which comprises a metallic connection structure, an electronic component mounted on the metallic connection structure, and an encapsulant encapsulating at least part of the electronic component and of the metallic connection structure, wherein an exposed part of the metallic connection structure comprises an intermetallic compound.

According to an exemplary embodiment, a simple and efficient package manufacture may be made possible by applying a solderable or sinterable metallic connection structure on a sacrificial or temporary carrier, which will be removed later before completing the manufacturing process. After assembling an electronic component on the applied metallic connection structure and subsequent encapsulation for firmly holding the parts together, the sacrificial carrier may be removed for rendering the metallic connection structure at least partially accessible. This exposing process may simplify subsequent electrical and mechanical coupling of the package with an electronic periphery. The mentioned manufacturing process may ensure a compact design of the manufactured package, since the sacrificial carrier may be removed so that a carrier-less package with small dimensions can be obtained.

Advantageously, an intermetallic compound may be formed as an interface between the sacrificial carrier and the solderable or sinterable metallic connection structure when the sacrificial carrier comprises or consists of a metallic material. Such an intermetallic compound may be exposed in the readily manufactured package and may promote an electric and mechanical connection of the package with an electronic periphery, such as a printed circuit board. Descriptively speaking, the presence of the intermetallic compound may be a fingerprint of embodiments of the above-described manufacturing method when an appropriate metallic sacrificial carrier is implemented.

In the following, further exemplary embodiments of the method and the package will be explained.

In the context of the present application, the term “package” may particularly denote an electronic device comprising one or more electronic components being at least partially encapsulated by an encapsulant. For instance, such a package may be a module.

In the context of the present application, the term “metallic connection structure” may particularly denote any metallic structure capable of establishing, directly or indirectly, a mechanical and/or an electrical connection between the package and an electronic periphery, such as a mounting base (for instance a printed circuit board). For example, a metallic connection structure may comprise a solder material, a sinter material, electrically conductive glue or any other metallic medium with connection capability.

In the context of the present application, the term “metallic connection structure comprising a solder or sinter material” may particularly denote a metallic connection structure capable of establishing a solder or sinter connection. A solder may be a fusible metal alloy used to create a permanent bond between metallic elements. Solder may be melted in order to adhere to and connect the metallic elements after cooling. Hence, a solder may be an alloy suitable for soldering and may have a lower melting point than the metallic elements being joined. A sinter material may denote a material suitable for establishing a connection between metallic elements by sintering. Sintering may denote a process of compacting and forming a solid mass of material by heat and/or pressure without melting it to the point of liquefaction. During sintering, atoms in the materials may diffuse across the boundaries of the panicles, fusing the particles together and creating one solid piece. A solder material may comprise a granulate.

In the context of the present application, the term “sacrificial carrier” may particularly denote a temporary support structure on which a metallic connection structure and at least one electronic component may be assembled prior to encapsulation. After encapsulation, the sacrificial carrier may be removed or sacrificed partially or entirely, so that no material or not the entire material of the sacrificial carrier forms part of the readily manufactured package.

In the context of the present application, the term “electronic component” may in particular encompass a semiconductor chip (in particular a power semiconductor chip, an active electronic device (such as a transistor), a passive electronic device (such as a capacitance or an inductance or an ohmic resistance), a sensor (such as a microphone, a light sensor or a gas sensor), an actuator (for instance a loudspeaker), and a microelectromechanical system (MEMS). However, in other embodiments, the electronic component may also be of different type, such as a mechatronic member, in particular a mechanical switch, etc.

In the context of the present application, the term “encapsulant” may particularly denote a substantially electrically insulating and preferably thermally conductive material surrounding at least part of an electronic component, at least part of a metallic connection structure and/or at least part of a sacrificial carrier. For instance, the encapsulant may be a mold compound and may be created for example by transfer molding. Alternatively, the encapsulant may be a casting compound formed by casting.

In the context of the present application, the term “intermetallic compound” may particularly denote a composite material reliably connecting component and carrier and comprising a plurality of different metallic constituents. For instance, such an intermetallic compound may be formed by solderable or sinterable material (for example comprising tin) and at least one additional metal (such as copper) originating from a metallic sacrificial carrier. For example, an intermetallic compound may be a mixture of at least two different intermetallic materials, such as tin, palladium, gold, silver, nickel and/or copper. For instance, the intermetallic compound may form an intermetallic mesh structure, i.e. a network of metallic structures of different metallic materials in a metallic matrix.

In an embodiment, the method comprises providing the sacrificial carrier to be temperature stable at least up to 300° C. This may ensure that the sacrificial carrier can withstand a reflow process for treating the solder or sinter material of the metallic connection structure and/or a molding process.

In an embodiment, the method comprises providing the sacrificial carrier as one of the group comprising a strip, a plate, and a frame. The sacrificial carrier may have a planar shape. Providing a planar strip, plate or frame as sacrificial carrier may simplify the manufacturing process.

In an embodiment, the method comprises providing the sacrificial carrier comprising a metal (in particular copper) and/or a ceramic. For example, the carrier comprises a leadframe structure (for instance made of copper). Hence, the sacrificial carrier may be embodied as patterned metal plate and thus in a simple and easily processable way. However, the sacrificial carrier may be alternatively embodied in another way, for instance as a central electrically insulating and thermally conductive sheet (for instance made of a ceramic), covered on one or both opposing main surfaces thereof with an electrically conductive layer (such as a copper of aluminum layer). For example, a sacrificial carrier may be embodied as a DAB (Direct Aluminum Bonding), DCB (Direct Copper Bonding) substrate, etc. Furthermore, the sacrificial carrier may also be configured as Active Metal Brazing (AMB) substrate.

In an embodiment, the method comprises applying the metallic connection structure by at least one of the group comprising depositing and printing, in particular stencil printing, screen printing or inkjet printing. Preferably, the metallic connection structure may be printed as one more pads on the sacrificial carrier. Stencil priming may denote a process of depositing a metallic connection structure, such as solder paste or sinter paste, on the sacrificial carrier to establish an electrical connection with one or more subsequently assembled electronic components. Screen printing may denote a printing technique where a mesh is used to transfer a metallic connection structure on the sacrificial carrier, except in areas made impermeable to the metallic connection structure 1w a blocking stencil. A blade or squeegee may be moved across the screen to fill the open mesh apertures with the metallic connection structure during printing. Inkjet printing may denote a printing process that creates an image of printed material by propelling droplets of an ink-type metallic connection structure onto the sacrificial carrier.

In an embodiment, the method comprises mounting the electronic component on the metallic connection structure by at least one component contact. Such a component contact may be an electrically conductive structure serving as a component interface for transmitting and/or receiving signals or electric energy. For example, such component contacts may comprise at least one metal pillar (such as a copper pillar), at least one metal bump or metal ball, and/or at least one metal pad (in particular with circular or rectangular geometry).

In an embodiment, the method comprises inserting the at least one component contact into the metallic connection structure. In particular, the at least one component contact may be pressed or immersed into a metallic connection structure being still present in a deformable phase, for instance as paste. This may allow to create a reliable large-area electric connection between electronic component and metallic connection structure.

In an embodiment, the method comprises re-adjusting a profile of the metallic connection structure after the mounting. After the deposition or printing process for applying the metallic connection structure on the sacrificial carrier, at least one physical property of the metallic connection structure may be adjusted by a specific treatment of the metallic connection structure. For instance, the re-adjustment may be a re-shaping of the metallic connection structure.

In an embodiment, the method comprises re-adjusting the profile of the metallic connection structure by at least one of the group comprising a curing process, a reflow process, and diffusion bonding. In particular, the process of re-adjusting the profile of the metallic connection structure may involve a heating to an elevated temperature, for example above 200° C. For example, the reflow process may be reflow soldering, when the metallic connection structure is a solder structure. In particular, reflow soldering may denote a process in which a solder paste (i.e. a sticky mixture of powdered solder and flux) is used to form a connection with the at least one electronic component. By subjecting the preform of the package to controlled heat, the solder paste reflows in a molten state, creating permanent solder joints. Diffusion bonding may denote a solid-state welding technique for joining different metallic structures. Diffusion bonding may operate based on solid-state diffusion, wherein the atoms of two solid, metallic surfaces intersperse themselves at an elevated temperature below the melting temperature of the involved materials.

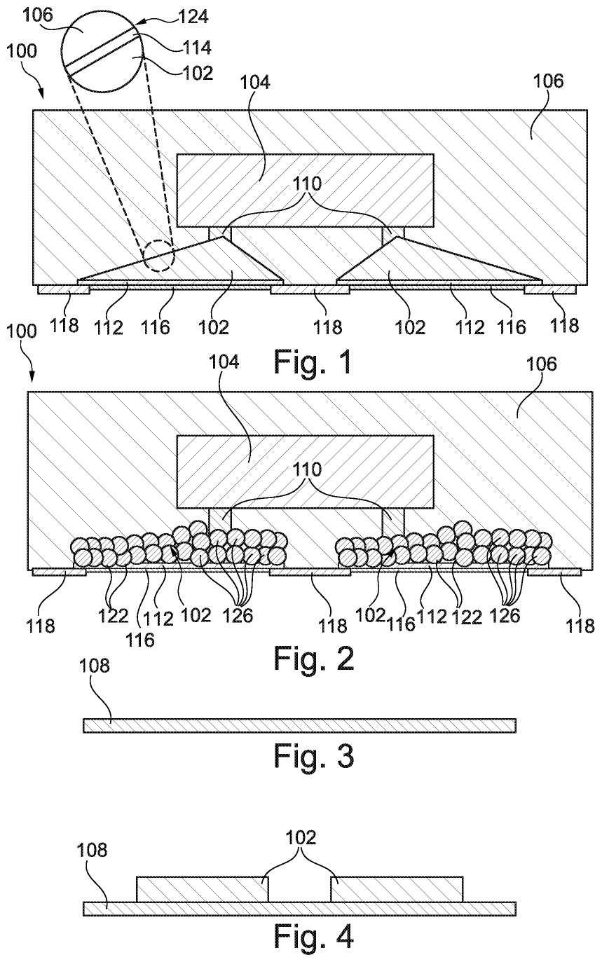

In an embodiment, the method comprises re-adjusting the profile of the metallic connection structure by locally thickening the metallic connection structure selectively in a connection region to the at least one electronic component. In particular, the re-adjustment may be an adjustment of the profile to have a thicker metallic connection structure portion between the sacrificial carrier and an electrically conductive component contact of the electronic component compared to a thinner metallic connection structure elsewhere. This may improve the electric reliability of the manufactured package. Consequently, the metallic connection structure may be locally thickened in a connection region to the electronic component. For example, the metallic connection structure is substantially triangular-shaped in a cross-sectional view (see for example FIG. 1 or FIG. 7).

In an embodiment, the method comprises forming an intermetallic compound in the metallic connection structure at an interface to the sacrificial carrier, in particular by diffusion or migration of material of the sacrificial carrier into the metallic connection structure. The formation of an intermetallic compound comprising metallic materials both of the sacrificial carrier and of the metallic connection structure may further improve the reliability of an electric connection to which said intermetallic compound contributes.

In an embodiment, the method comprises, before the encapsulating, forming a dielectric film in an exposed surface region of the metallic connection structure. Correspondingly, the package may comprise a dielectric film in a surface region of the metallic connection structure being covered by the encapsulant. For instance, said dielectric film may be a metal oxide layer formed on an exposed surface of the metallic connection structure during the above-described re-adjustment process, in particular when executed at elevated temperature in an oxygen atmosphere. Advantageously, such a dielectric film may limit and thereby control the material flow of heated metallic connection structure during the re-adjustment process.

In an embodiment, the method comprises removing the sacrificial carrier by at least one of the group consisting of selective etching, grinding, releasing and peeling off. For instance, a sacrificial carrier made of copper may be removed by selective copper etching. By a selective etching process, it may be ensured that only material of the sacrificial carrier, but substantially no other materials of the preform of the package, is removed. It is also possible that the sacrificial carrier is removed mechanically by back grinding the preform of the package from the backside. It is also possible to release the sacrificial carrier from the backside triggered, for instance by pressure and/or elevated temperature. Furthermore, the sacrificial carrier may be pulled away from the rest of the package.

In an embodiment, the method comprises removing the sacrificial carrier using an intermetallic compound of the metallic connection structure at an interface to the sacrificial carrier as stop layer. Advantageously, the intermetallic compound comprising metallic material from the sacrificial carrier and from the metallic connection structure may have a larger hardness than the involved individual metallic structures. Consequently, the intermetallic compound may be highly appropriate for functioning as stop layer for defining a stop position where the sacrificial carrier material removal process stops. This renders the process control more precise and simpler.

In an embodiment, the method comprises applying a surface finish selectively to an exposed surface region of the metallic connection structure after the removing. For instance, a surface finish may be an electrically conductive material configured for protecting the metallic connection structure or the intermetallic compound from oxidizing. Moreover, a surface finish may promote solderability and electrical reliability and performance. For example, such a surface finish may be made of tin or nickel palladium gold.

In an embodiment, the method comprises forming a patterned dielectric protection layer, in particular a solder resist, for exposing at least one defined surface area of the metallic connection structure or a surface finish on the metallic connection structure. Advantageously, such a solder resist may be embodied as a lacquer-like polymer film applied to a portion of the exposed metallic connection structure or intermetallic compound to prevent undesired solder bridges between closely spaced solder pads.

In an embodiment, the metallic connection structure comprises or consists of an interconnected granular material, preferably sinterable granular material. Such an embodiment is shown in FIG. 2. In particular, the use of interconnected granular material for forming the metallic connection structure may allow to form more squarish pads and may reduce a shorting risk.

In an embodiment, the package comprises an electric connection bump, in particular a solder bump, formed on the intermetallic compound. Such electric connection bumps may allow to electrically mount the package on a mounting base, such as a printed circuit board, by a solder connection or the like in between.

In an embodiment, the package comprises a plurality of electronic components each mounted on at least one assigned one of a plurality of metallic connection structures. Thus, more than one electronic component may be encapsulated in the package. For example, different electronic components of a common package may be electrically coupled with each other for functionally cooperating.

In an embodiment, the electronic component is mounted on a plurality of spatially separated metallic connection structures. By such a configuration, electronic components with a plurality of pads or other kind of component contacts may be properly electrically connected.

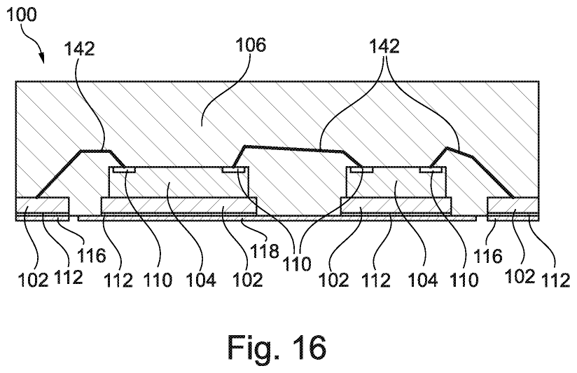

In an embodiment, an active region of the electronic component faces the metallic connection structures or faces away from the metallic connection structure. An active region of an electronic component may be a portion of a semiconductor substrate in which at least one integrated circuit is monolithically integrated. When an active region faces the metallic connection structure (see for instance the flip chip configuration of FIG. 1), the electrically conductive connection paths are very short. However, it is also possible that an active region faces away from the metallic connection structure (as in FIG. 16). In such a scenario, an electric connection between an active region and the metallic connection structure may be formed by one or more bond wires or by one or more clips.

In an embodiment, a vertical thickness of the intermetallic compound is in a range from 5 μm to 50 μm, in particular in a range from 10 μm to 30 μm, more particularly in a range from 10 μm to 20 μm. Advantageously, the described intermetallic compound may be provided with a very low thickness. This keeps the electronic system compact in a vertical direction and ensures a high mechanical, thermal and electrical reliability of the electronic system.

In an embodiment, at least one of the at least one electronic component is a bare die. By embodying the at least one electronic component as a non-encapsulated chip, i.e. a pure semiconductor chip without additional dielectric encapsulant, the compactness of the package may be further enhanced.

In an embodiment, the electronic system comprises a plurality of (in particular electronic) components mounted on the metallic connection structure or on different metallic connection structures. Thus, the package may comprise one or more electronic components (for instance at least one passive component, such as a capacitor, and at least one active component, such as a semiconductor chip).

In an embodiment, an electronic device is provided which comprises the above-mentioned package and a mounting base (such as a printed circuit board, PCB) on which the package is mounted and is electrically coupled. Such a mounting base may be an electronic board serving as mechanical base for the package.

In an embodiment, the package is configured as power module, for instance molded power module. For instance, an exemplary embodiment of the electronic system may be an intelligent power module (IPM). Another exemplary embodiment of the package is a dual inline electronic system (DIP).

In an embodiment, the electronic component is configured as a power semiconductor chip. Thus, the electronic component (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide). A semiconductor power chip may comprise one or more field effect transistors, diodes, inverter circuits, half-bridges, full-bridges, drivers, logic circuits, further devices, etc.

As substrate or wafer forming the basis of the electronic components, a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages will become apparent from the following description and the appended claims, taken in conjunction with the accompanying drawings, in which like parts or elements are denoted by like reference numbers.

The illustration in the drawing is schematically and not to scale.

FIG. 1 illustrates a cross-sectional view of a package 100 according to an exemplary embodiment.

The package 100 comprises an electronic component 104. For instance, the electronic component 104 is a semiconductor chip such as a semiconductor power chip (for instance a MOSFET chip for power applications).

The electronic component 104 has component contacts 110 (such as electrically conductive pillars or pads) for providing an electric contact to integrated circuit elements in an interior of the electronic component 104.

Each component contact 110 is mounted on and is electrically coupled with a respective one of metallic connection structures 102. Hence, different component contacts 110 of the electronic component 104 are mounted on and are electrically coupled with an assigned one of a plurality of spatially separated metallic connection structures 102. Each metallic connection structure 102 may comprise a solder material, such as tin. In the shown embodiment, each metallic connection structure 102 has a substantially triangular-shaped in the illustrated cross-sectional view of FIG. 1. More specifically, each of the metallic connection structures 102 is locally thickened in a connection region to a respective one of the component contacts 110 of the electronic component 104. This may improve the reliability of the electric connection between the connection contacts 110 and the metallic connection structures 102.

The electronic component 104 is mounted in FIG. 1 in a flip chip configuration. Consequently, an active region of the electronic component 104 is located on a bottom main surface of the electronic component 104 and therefore faces the metallic connection structures 102. This keeps the electric connection paths short and contributes to a compact design of the package 100.

An encapsulant 106 encapsulates the electronic component 104 including its component contacts 110 and encapsulates part of the metallic connection structures 102. For instance, encapsulant 106 may be a mold compound.

A portion of the metallic connection structures 102, being exposed beyond the encapsulant 106, comprises an intermetallic compound 112 being embodied as multi-metal film. The intermetallic compound 112 comprises a solderable material, such as tin, from which the rest of the metallic connection structure 102 is made. Furthermore, the intermetallic compound 112 comprises another metallic material, such as copper, being a residue of a temporary copper carrier (see reference sign 108 in FIG. 3) which has been removed from the package 100 before completing its manufacture. The intermetallic compound 112 has a high hardness which improves the mechanical reliability of the package 100, promotes the reliable electric connectivity of package 100, and may additionally function as stop layer during a selective etching process of removing the sacrificial carrier 108 (see FIG. 8).

As shown in a detail 124 FIG. 1, package 100 comprises a dielectric film 114 in a surface region of each respective metallic connection structure 102 being covered by the encapsulant 106. Advantageously, the dielectric film 114, which may be oxidized metallic material of the metallic connection structure 102, may limit solder flow during re-shaping the substantially triangular metallic connection structures 102 during a manufacturing process, as described below in further detail.

Furthermore, part of an exterior surface of the metallic connection structures 102 is covered by a surface finish 116, such as nickel palladium gold, for protecting the electrically conductive surface of the package 100 from oxidizing or corroding. Moreover, package 100 comprises a patterned dielectric protection layer 118 which may be embodied as a solder resist and which may serve for exposing only a defined surface area of the surface finish 116 on the metallic connection structures 102. The patterned dielectric protection layer 118 prevents undesired solder bridges and the like. More specifically, the patterned dielectric protection layer 118 may define a desired pitch and may remove imperfections at the boundary to the pads.

Due to the removal of the sacrificial carrier 108 before completing manufacture of the package 100, the package 100 is a carrier-less package, i.e. does not comprise any carrier. Advantageously, this leads to a compact design of the package 100.

A method for manufacturing the package 100 of FIG. 1 will be described below referring to FIG. 3 to FIG. 10.

FIG. 2 illustrates a cross-sectional view of a package 100 according to another exemplary embodiment.

The package 100 according to FIG. 2 differs from the package 100 according to FIG. 1 particular in that, according to FIG. 2, the metallic connection structures 102 are formed of an interconnected granular material 122. In other words, the metallic connection structures 102 of FIG. 2 are formed by interconnected electrically conductive granulate particles 126 (for instance formed by sintering material). Advantageously, this may lead to a more squarish pad shape than in FIG. 1 and may reduce or even minimize a risk of electric shortage during operation of package 100.

FIG. 3 to FIG. 10 are cross-sectional views of structures obtained during manufacturing a package 100, as the one shown in FIG. 1, according to an exemplary embodiment.

Referring to FIG. 3, a sacrificial carrier 108 is provided as a planar electrically conductive body, for instance as copper strip. Advantageously, the sacrificial carrier 108 may be made of a material being temperature stable at least up to 300° C. in order to withstand a reflow process (see FIG. 6) and a molding process (see FIG. 7).

Hence, it is possible to use a blank copper strip as sacrificial carrier 108, which keeps the manufacturing effort small. The sacrificial carrier 108 may be stamped for forming indexing holes (not shown).

Referring to FIG. 4, a plurality of metallic connection structures 102 are applied on the sacrificial carrier 108. In FIG. 4, the metallic connection structures 104 have a substantially rectangular cross-sectional shape. For example, the metallic connection structures 102 may comprise a solder or sinter material, such as solder paste or sinter paste. Such a deformable material for the metallic connection structures 102 may be applied to the sacrificial carrier 108 by depositing or printing. Preferably, the metallic connection structures 102 may be applied by stencil printing. Stencil printing may be appropriate to create a pitch and size to comply with an electronic component 104 to be mounted subsequently. Thus, the metallic connection structures 102 may be applied by screen printing of soft materials, for example as solder or sintering pads.

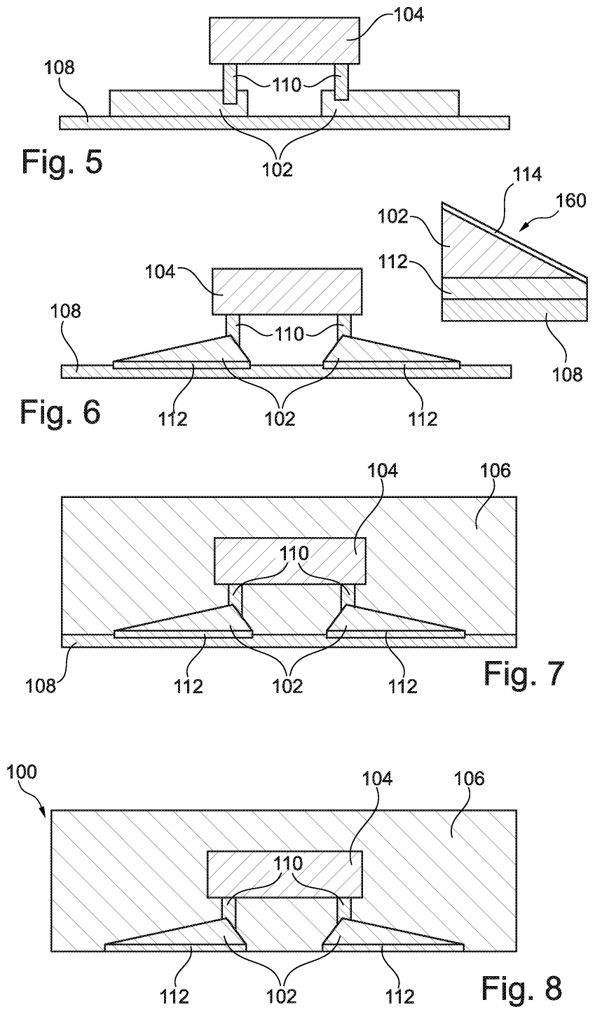

Referring to FIG. 5, an electronic component 104, such as a bare die, is mounted on the metallic connection structures 102. Thus, a die bonding process may be carried out. More specifically, each of a plurality of component contacts 110 of the electronic component 104 may be inserted into an assigned one of the still deformable metallic connection structures 102 with direct physical contact between sidewalls of the component contacts 110 and an assigned metallic connection structure 102. By said insertion of the component contacts 110 into the metallic connection structures 102 to establish a contact not only on a bottom surface but also at sidewall areas of the component contacts 110, a reliable electric connection between a respective metallic connection structure 102 and a respective component contact 110 may be promoted. This may ensure a high electric reliability of the manufactured package 100. For instance, each component contact 110 may be a copper pillar. Descriptively speaking, a respective metal pillar may be used to contact a respective printed pad.

Referring to FIG. 6, a profile of the—up to now rectangular—metallic connection structures 102 is re-adjusted into a substantially triangular shape. By such a re-adjusting process, the profile of the metallic connection structure 102 may be modified in accordance with the requirements of a certain application. For instance, the re-adjusting may be executed by carrying out a reflow process (such as reflow soldering) or by diffusion bonding. In the present example, the re-adjusting leads to a local thickening of each of the metallic connection structures 102 selectively in a connection region to the respectively assigned component contact 110 of the electronic component 104. Hence, the connection area between a respective metallic connection structure 102 and its assigned component contact 110 may be increased by the re-adjusting, thereby improving the reliability of the electric and mechanical connection in between.

As can be taken from a detail 160 in FIG. 6, due to the elevated temperature (for example 230° C. or more) during the reflow process, an intermetallic compound 112 may be formed in an interface region between the metallic connection structure 102 and the sacrificial carrier 108. This may be caused by a phenomenon such as diffusion and/or migration of material of the sacrificial carrier 108 into the metallic connection structure 102, and/or vice versa. Advantageously, the intermetallic compound 112 may have a pronounced hardness and may be highly suitable for establishing an electric connection with an electronic periphery.

As shown in detail 160 as well, said elevated temperature may form a dielectric film 114 in an exposed surface region of the metallic connection structures 102 by oxidizing exposed metallic material thereof. Thus, a metal oxide film may be formed at an outer surface of the metallic connection structure 102. Advantageously, dielectric film 114 may limit a flow of material of the metallic connection structures 102 which may become flowable during the reflow process.

In particular, the mentioned reflow process (for profile adjustment) can be adjusted to comply with a desired internal pad appearance, for instance smooth or granular. For instance, the reflow process may be executed for adjusting the profile of the metallic connection structures 102 so as to have a thicker layer of an intermetallic compound 112 between the sacrificial carrier 108 of copper and the printed pads constituting the metallic connection structures 102.

Again referring to FIG. 2, by correspondingly adjusting a reflow profile and/or by changing materials (for instance by using sintering material), structures 102 can be shaped in granular way as well.

Referring to FIG. 7, the electronic component 104 including its component contacts 110 as well as part of the metallic connection structure 102 may be encapsulated by an encapsulant 106. Encapsulant 106 may be formed by molding.

Referring to FIG. 8, the sacrificial carrier 108 may then be removed from the rest of the pre-form of the package 100 to thereby expose part the intermetallic compound 112 of the metallic connection structures 102. Advantageously, the sacrificial carrier 108 may be removed by selective copper etching using the very hard intermetallic compound 112 at the bottom of the metallic connection structures 102 at an interface to the sacrificial carrier 108 as stop layer. Thus, a selective copper etching process will automatically stop (or will be at least delayed extremely) when reaching the very hard intermetallic compound 112. This simplifies process control for removing sacrificial carrier 108.

Alternatively, the sacrificial carrier 108 may be removed by mechanically grinding, temperature- or pressure-triggered release or by peeling it off.

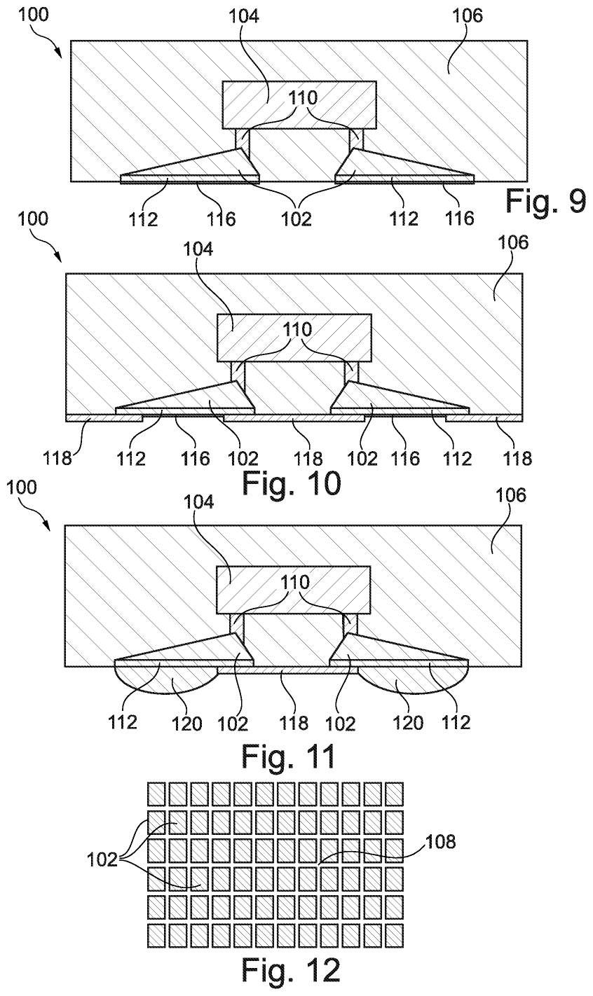

Referring to FIG. 9, an optional electrically conductive surface finish 116 may be formed selectively to an exposed surface region of the intermetallic compound 112 of the metallic connection structures 102. For instance, surface finish 116 may be formed by nickel palladium gold plating. Surface finish 116 may protect the metallic surfaces, in particular against oxidizing.

Referring to FIG. 10, a patterned dielectric protection layer 118 may be formed in form of a solder resist for exposing only defined surface areas of the surface finish 116 on the intermetallic compound 112 of the metallic connection structures 102. This may prevent formation of undesired solder bridges. Thus, the final pads of package 100 may be defined by the solder mask. For example, the solder mask may be applied by jet printing.

After formation of the solder mask, a curing process may be executed. Moreover, an array cut and a package singulation may be carried out (not shown).

FIG. 11 illustrates a cross-sectional view of a package 100 according to still another exemplary embodiment.

In the embodiment of FIG. 11, surface finish 116 is omitted (although it can be present). Thus, nickel palladium gold plating can be saved in the embodiment of FIG. 11. Furthermore, package 100 according to FIG. 11 comprises a plurality of electric connection bumps 120, which are here embodied as solder bumps, formed on the intermetallic compound 112 of each metallic connection structure 102. To put it shortly, it may be possible to add additional solder to the exposed pads (for example for having more solder mass for test probing purpose).

FIG. 12 to FIG. 14 are plan views of structures obtained during manufacturing packages 100 according to an exemplary embodiment. This embodiment illustrates a printed pad grid as a basis for die bonding. The illustrated pad grid provide a user with a high degree of flexibility what concerns package scalability.

Referring to FIG. 12, a matrix-like pattern of metallic connection structures 102 (which may be denoted as pads) printed on a (for example frame-type) sacrificial carrier 108 is shown. As shown, the mentioned pads may be printed with fixed grids, size and pitch.

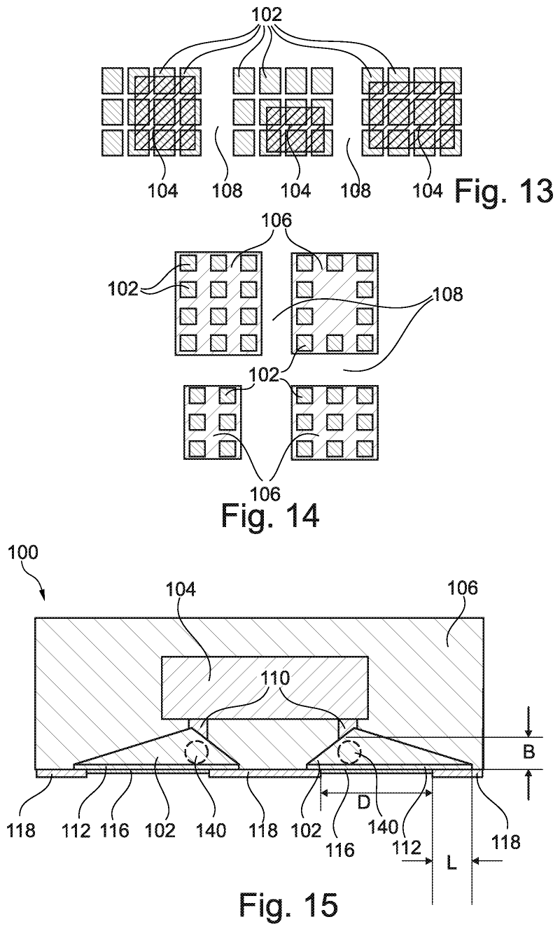

Referring to FIG. 13, a plurality of electronic components 104 may be assembled on groups of metallic connection structures 102. Thus, the array of pads according to FIG. 12 simplifies a subsequent die bonding process and increases the flexibility thereof. In particular, the array of pads according to FIG. 12 is capable of accepting electronic components 104 of different dimensions, in particular different chip sizes. FIG. 13 shows examples of electronic components 104 being connected with 6, 9 or 12 metallic connection structures 102.

Referring to FIG. 14, different pre-forms of packages 100 are illustrated after encapsulation by an encapsulant 106.

Hence, processes such as molding, carrier removal, plating, solder mask printing may be executed in common for the various pre-forms of packages 100. By using different solder mask stencils, different footprints can be generated. Cutting regions of different size yields different package sizes.

Hence, a common sacrificial carrier 108 with a plurality of metallic connection structures 102 thereon may be used for manufacturing packages 100 with different properties.

FIG. 15 illustrates a cross-sectional view of a package 100 according to an exemplary embodiment.

Package 100 according to FIG. 15 is of the type of package 100 according to FIG. 1. FIG. 15 shows some advantageous properties and parameters of package 100.

In regions 140, the solder bump-type metallic connection structures 102 are fused with pillar-type (or pad-type) component contacts 110 to achieve a proper mechanical integrity and a reliable electric connection. Furthermore, this may avoid any issues with oxidation.

As shown in FIG. 15 as well, an exposed diameter, D, of a window in the patterned dielectric protection layer 118 may be for example 200 μm. A maximum vertical extension, B, of a substantially triangular metallic connection structure 102 may be for example 30 μm. An extension, L, of a respective metallic connection structure 102 beyond the window defined in the patterned electric protection layer 118 may be for example 100 μm.

FIG. 16 illustrates a cross-sectional view of a package 100 according to still another exemplary embodiment.

Package 100 according to FIG. 16 comprises a plurality of electronic components 104 each mounted on an assigned one of a plurality of metallic connection structures 102. According to FIG. 16, an active region of each of the electronic components 104 faces away from the assigned metallic connection structure 102. More specifically, the active region of each electronic component 104 is located at its top main surface. To electrically connect the active regions of the electronic components 104, bond wires 142 (or clips, not shown) may connect component contacts 110 (pads in the shown embodiment) at the active regions with metallic connection structures 102 without electronic component mounted thereon.

The bottom main surfaces of the electronic components 104 may or may not comprise active regions as well. When active regions are provided both on the bottom main surface and on the top main surface of an electronic component 104, a device with vertical current flow may be encapsulated in the package 100.

For instance, package 100 according to FIG. 16 may function as (for example screen printed) high voltage driver. Still referring to FIG. 16, it may be possible to create floating pads and cover pads with solder mask.

The embodiment of FIG. 16 also differs for instance from the embodiment of FIG. 1 in that component contacts 110 may be embodied as metal pads rather than as metal pillars.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A method of manufacturing a package, wherein the method comprises:
applying a metallic connection structure, which comprises a solder or sinter material, on a sacrificial carrier;
mounting an electronic component on the metallic connection structure;
encapsulating at least part of the electronic component and of the metallic connection structure by an encapsulant; and
thereafter removing the sacrificial carrier to thereby expose at least part of the metallic connection structure.

2. The method according to claim 1, wherein the method comprises providing the sacrificial carrier to be temperature stable at least up to 300° C.

3. The method according to claim 1, wherein the method comprises providing the sacrificial carrier as one of the group comprising a strip, a plate, and a frame.

4. The method according to claim 1 wherein the method comprises providing the sacrificial carrier comprising a metal and/or a ceramic.

5. The method according to claim 1, wherein the method comprises applying the metallic connection structure by at least one of the group comprising depositing and printing, in particular stencil printing, screen printing or inkjet printing.

6. The method according to claim 1, wherein the method comprises mounting the electronic component on the metallic connection structure by at least one component contact, in particular at least one of the group comprising at least one metal pillar, at least one metal bump, at least one metal ball, and at least one metal pad.

7. The method according to claim 6, wherein the method comprises inserting the at least one component contact into the metallic connection structure, in particular with direct physical contact between at least part of a sidewall of a respective component contact and the metallic connection structure.

8. The method according to claim 1, wherein the method comprises re-adjusting a profile, in particular a shape, of the metallic connection structure after the mounting.

9. The method according to claim 8, wherein the method comprises re-adjusting the profile of the metallic connection structure by at least one of the group comprising a curing process, a reflow process, and diffusion bonding.

10. The method according to claim 8, wherein the method comprises re-adjusting the profile of the metallic connection structure by locally thickening the metallic connection structure selectively in a connection region to the at least one electronic component, in particular selectively in a connection region to at least one component contact of the at least one electronic component.

11. The method according to claim 1, wherein the method comprises forming an intermetallic compound in the metallic connection structure at an interface to the sacrificial carrier, in particular by diffusion or migration of material of the sacrificial carrier into the metallic connection structure.

12. The method according to claim 1, wherein the method comprises, before the encapsulating, forming a dielectric film in an exposed surface region of the metallic connection structure.

13. The method according to claim 1, wherein the method comprises removing the sacrificial carrier by at least one of the group comprising selective etching, grinding, releasing and peeling off.

14. The method according to claim 1, wherein the method comprises removing the sacrificial carrier using an intermetallic compound of the metallic connection structure at an interface to the sacrificial carrier as stop layer.

15. The method according to claim 1, wherein the method comprises applying a surface finish selectively to an exposed surface region of the metallic connection structure after the removing.

16. The method according to claim 1, wherein the method comprises forming a patterned dielectric protection layer, in particular a solder resist, for exposing at least one defined surface area of the metallic connection structure or of a surface finish on the metallic connection structure.

17. A package comprising:
a metallic connection structure;
an electronic component mounted on the metallic connection structure; and
an encapsulant encapsulating at least part of the electronic component and of the metallic connection structure;
wherein an exposed part of the metallic connection structure comprises an intermetallic compound.

18. The package according to claim 17, wherein the metallic connection structure is locally thickened in a connection region to the electronic component.

19. The package according to claim 17, wherein the metallic connection structure is substantially triangular-shaped in a cross-sectional view.

20. The package according to claim 17, comprising at least one of the following features:
wherein the metallic connection structure comprises or consists of an interconnected granular material;
comprising a dielectric film in a surface region of the metallic connection structure being covered by the encapsulant;
comprising an electric connection bump, in particular a solder bump, formed on the intermetallic compound;
comprising a plurality of electronic components each mounted on at least one assigned one of a plurality of metallic connection structures;
wherein the electronic component is mounted on a plurality of spatially separated metallic connection structures;
wherein an active region of the electronic component faces the metallic connection structure or faces away from the metallic connection structure;
wherein the metallic connection structure comprises a solder or sinter material;
wherein the package is a carrier-less package.
